(19) United States
(12) Patent Application Publication
(10) Pub. No.: US 2025/0383384 A1
(43) Pub. Date: Dec. 18, 2025

(54) METHOD FOR APPLYING A DISCRETE FOURIER TRANSFORM, DFT, TO A SEQUENCE OF SAMPLES OF A SENSOR SIGNAL, PROCESSOR CIRCUIT FOR PERFORMING THE METHOD, RADAR SENSOR AND MOTOR VEHICLE

(71) Applicant: Continental Automotive Technologies GmbH, Hannover (DE)

(72) Inventors: Mario Schuehler, Effeltrich (DE); Burak Sahinbas, Regensburg (DE); Lars Weisgerber, Regensburg (DE); Thomas Kötter, Regensburg (DE)

(73) Assignee: Continental Automotive Technologies GmbH, Hannover (DE)

(21) Appl. No.: 19/241,647

(22) Filed: Jun. 18, 2025

(30) Foreign Application Priority Data
Jun. 18, 2024 (DE) 10 2024 205 594.8

(51) Int. Cl. G01R 23/16; B60W 30/09; B60W 30/095; B60W 50/00; G01S 13/04; G01S 13/931

(52) U.S. Cl. CPC G01R 23/16; B60W 30/09; B60W 30/0956; B60W 50/00; G01S 13/04; G01S 13/931; B60W 2050/0012; B60W 2050/0052; B60W 2420/408

(57) ABSTRACT

A method for applying a Discrete Fourier Transform (“DFT”) to a sequence of N samples of a sensor signal, with N>2. The resulting DFT spectral coefficients are updated iteratively whenever a new one of the samples or a sub-group of consecutive new samples, comprising a predefined number J of samples, with 1<J<N, is received.

### CROSS-REFERENCE TO RELATED APPLICATIONS

The present application claims priority to German patent application No. 10 2024 205 594.8, filed Jun. 18, 2024, which is hereby incorporated by reference.

### TECHNICAL FIELD

The technical field relates generally to calculating a discrete Fourier transform (“DFT”) of a sensor signal using an implementation with a small memory footprint, a processor circuit for performing the transform, and a sensor device with such a processor circuit.

### BACKGROUND

A sensor device (like a RADAR device or a microphone), may rely or depend on a Fourier spectral analysis of its sensor signal. The spectral analysis in real-time signal processing applications relies on the acquisition of a certain amount N of signal samples (i.e., a frame) for calculating a spectrum. When the samples are acquired, the fast Fourier transform (“FFT”) is normally applied to all N signal samples at once. The number of samples N defines the number of frequency points P and therefore the resolution in the image or Fourier domain.

In a motor vehicle, hardware resources, in particular memory, can be scarce. As all N signal samples must be acquired and stored in advance to the spectral transform, the memory consumption can become very high. This makes embedding such a DFT in a computing platform expensive as bigger memory modules are needed.

If the spectral contribution of a single signal sample xₙ could be computed upon its acquisition without having to acquire all samples first, the memory consumption could be reduced. Signal samples that have already been considered for the spectral computation could be dropped from the memory.

Therefore, there is an opportunity to provide a DFT signal transform with low memory requirement or low memory footprint.

### SUMMARY

One embodiment is a method for applying a P-dimensional Discrete Fourier Transform (“DFT”) to a sequence or frame of N samples of a sensor signal. P is the number of frequency bins or frequency points fₚ of the DFT and N is the number of samples per frame or sequence. N can be in the range of 8 to 4096, just to name examples. Several consecutive frames of the sensor signal can be processed this way, but for describing or explaining the invention, the processing of one single frame is described only. The method includes the following steps that are executed by a processor circuit: receiving one of the samples at a time or successively and whenever a new one of the samples is received or whenever a sub-set of J of the N samples is received, i.e., a group or sub-group comprising J consecutive new samples, with 1<J<N:
providing, for each new or current sample xₙ, an order index n (current sample index n) indicating which one of the 1 to N samples has been received, wherein n is in 1, . . . , N; and
proving, for each new sample xₙ, a corresponding DFT vector \vec{d}⁽ⁿ⁾, wherein the DFT vector \vec{d}⁽ⁿ⁾ is selected or generated depending on the order index n of the sample xₙ, wherein the DFT vector \vec{d}⁽ⁿ⁾ comprises P phasor values that are derived from the frequency points fₚ of the P-dimensional DFT by S*exp(−i 2 π fₚ tₙ),
with p in 1, . . . , P the index of the phasor value in the DFT vector \vec{d}⁽ⁿ⁾ and S a scaling factor (e.g. 1/N or 1/sqrt(N)) and tₙ the sampling time tₙ of the new sample xₙ and i the imaginary unit with i²=−1; fₚ can be, e.g., set to p/N or a frequency value as is known for DFT phasor values; tₙ can be obtained as a receiving time when receiving the sample at or from the sensor, as a clock time or timestamp or counter value. The initial value t₁ can be set to 0 or an absolute time value, for example;
applying the respective new sample xₙ as a multiplication factor to its corresponding DFT vector \vec{d}⁽ⁿ⁾ for generating a respective spectral contribution vector Δ\vec{y}⁽ⁿ⁾=\vec{d}⁽ⁿ⁾xₙ;
adding the respective spectral contribution vector Δ\vec{y}⁽ⁿ⁾ to an accumulation vector \vec{y}⁽ⁿ⁾=Δ\vec{y}⁽ⁿ⁾+\vec{y}⁽ⁿ⁻¹⁾; where for each new frame it can be initialized as zero vector \vec{y}⁽⁰⁾=\vec{0}; and when for all N samples their corresponding resulting contribution vector has been added to the accumulation vector, providing the accumulation vector \vec{y}^{(N)} as the DFT spectral coefficients of the frame of the N samples. In particular it is chosen P=N. Note that 1, . . . , N and 1, . . . , P (and similar notations for J and M below) is the well-known notation for index ranges as is known from the prior art.

In other words, the resulting DFT spectral coefficients are updated iteratively whenever a new one of the samples or a group of J consecutive new samples, with 1<J<N, is received.

The method provides the advantage of computing the spectrum of a signal (DFT spectral coefficients) in a continuous way. The contribution of each signal sample xₙ to the spectrum over a certain number of samples is computed upon arrival and the respective signal sample can be dropped right after the computation from memory. It is not needed to store all N signal samples of a frame at the same time for performing the transform. This is technique of calculating the DFT is referred to as “streaming DFT” or SDFT in this document. The streaming or continuous computation of the spectrum does not introduce errors in the spectrum.

The disclosure also includes embodiments that provide additional technical advantages.

A further benefit is obtained by deleting the respective new sample when the corresponding contribution vector for that sample is calculated and deleting the respective contribution vector after adding it to the accumulation vector, such that at no point in time all N samples xₙ, with n in 1, . . . , N, nor their resulting contribution vector Δ\vec{y}⁽ⁿ⁾ are stored together in the processor circuit. Only the latest one sample or (for the group-wise transform) the latest at most J or 2J latest samples are stored. This provides the advantage that no memory for storing the complete frame of N samples at a time needs to be provided in the processor circuit (i.e. reduced memory footprint as compared to the need of keeping all N samples in memory for performing the transform). The processor circuit can come with a memory for less than N samples per channel (see the multi-channel solutions below).

A further benefit is obtained by generating at least some or all of the samples at sampling times with constant sampling period to (equidistant sampling), resulting in tₙ=tₙ₋₁+t₀ for n in 2, . . . . N and t₁ an initial time value, in particular t₁=0, and generating the respective DFT vector \vec{d}⁽ⁿ⁾ for the respective sample xₙ of order index n using a P-dimensional base DFT vector \vec{d}⁽⁰⁾ and the previous DFT vector \vec{d}⁽ⁿ⁻¹⁾ by applying an element-wise multiplication \vec{d}⁽ⁿ⁾=diag{\vec{d}⁽⁰⁾}\vec{d}⁽ⁿ⁻¹⁾, if n>1 and diag{⋅} the diagonal matrix, wherein \vec{d}⁽⁰⁾ comprises phasor elements exp(−i 2 T fₚ tₒ) with p in 1, . . . , P. The DFT vector \vec{d}⁽¹⁾ for the initial order index n=1 can be the base DFT vector \vec{d}⁽⁰⁾ or \vec{d}⁽¹⁾ can be selected for a predefined time value t₁, e.g. t₁=0. This implementation further reduced the memory requirement as only \vec{d}⁽⁰⁾ and \vec{d}⁽ⁿ⁻¹⁾ need to be held in memory at a time.

A further benefit is obtained by:
generating at least some or all of the samples at non-equidistant sampling times tₙ (non-equidistant sampling) and
providing a rasterized time pattern by defining a minimum time step width \hat{t}₀ and
generating the respective DFT vector \vec{d}⁽ⁿ⁾ for the respective sample of order index n using a P-dimensional base DFT vector \vec{\hat{d}}⁽⁰⁾ and the DFT vector \vec{d}⁽ⁿ⁻¹⁾ by applying a element-wise multiplication, wherein \vec{\hat{d}}⁽⁰⁾ comprises phasor elements exp(−i 2 π fₚ \hat{t}₀) with p in 1, . . . , P and a time difference tₙ−tₙ₋₁ of sampling time of the new sample xₙ and the preceding sample xₙ₋₁ is expressed as the integer multiple or the next larger integer multiple or the next smaller integer multiple

$$μ = [ \frac{{t}_{n} - {t}_{n - 1}}{{\hat{t}}_{0}} ]$$

of \hat{t}₀, with [⋅] the rounding operator (up or down), such that \vec{d}⁽ⁿ⁾=diag{\vec{\hat{d}}⁽⁰⁾}^{μ} \vec{d}⁽ⁿ⁻¹⁾.
   As non-equidistant sampling times can be handled, this implementation provides the advantage that is can compensate time jitter of a sensor clock, for example.

A further benefit is obtained by:
generating some or all of the samples at non-equidistant sampling times tₙ and
keeping stored M>1 pre-calculated vectors diag{\vec{\hat{d}}^{(m)}} for different time values {\hat{t}₁, . . . , \hat{t}_{M}} in memory as \vec{\hat{d}}^{(m)}, m=1 . . . . M, with phasor elements exp(−i 2 π fₚ \hat{t}ₘ), p=1, . . . , P, and for a given sample xₙ at sampling time tₙ the vector for index m=arg min|{tₙ−tₙ₋₁−\hat{t}ₘ} with the closest time-difference is applied by element-wise multiplication of the preceding DFT vector for providing the DFT vector \vec{d}⁽ⁿ⁾=diag{\vec{\hat{d}}^{(m)}}\vec{d}⁽ⁿ⁻¹⁾ for n>1. The first vector \vec{d}⁽¹⁾ can be calculated as described above.
   As pre-calculated phasor values are provided, this implementation provides the advantage that the amount of real-time calculations can be reduced.

A further benefit is obtained by receiving the new sample xₙ from a first channel 11 giving a new first-channel sample x(tₙ, τ₁) and receiving together with this new first-channel sample at least one further new sample x(tₙ, τ_{c}) for at least one further channel c, such that overall a respective new sample of C channels are received. The new samples x(tₙ, τ_{c}), c=1, . . . , C, are then transformed together for each channel, c=1, . . . , C. This results in a beneficial multi-channel implementation, as it can be used advantageously for RADAR sensors in particular, as is explained in further detail below.

A further benefit is obtained by:
generating some or all of the samples at non-equidistant sampling times tₙ and
providing for M>1 a set of possible time step widths

$$\{ {\hat{t}}_{1} , … , {\hat{t}}_{M} \}$$

and for the new sample xₙ it is taken the time step \hat{t}ₘ that is closest to the time difference tₙ−tₙ₋₁ of two consecutive samples

$${\vec{d}}^{( n )} = diag \{ {{d}^{\hat{\to }}}^{( m )} \} {\vec{d}}^{( n - 1 )} for n > 1 and m = 1 , … , M$$

with

$${{d}^{\hat{\to }}}^{( m )} = ( \begin{matrix}\begin{matrix}\begin{matrix}exp ( - i 2 π {f}_{1} {\hat{t}}_{m} ) \\ exp ( - i 2 π {f}_{2} {\hat{t}}_{m} )\end{matrix} \\ ⋮\end{matrix} \\ exp ( - i 2 π {f}_{P} {\hat{t}}_{m} )\end{matrix} )$$

$$and$$

$$m = argmin \vert \{ {t}_{n} - {t}_{n - 1} - {\hat{t}}_{m} \} \vert .$$

This provides the benefit of reducing the real-time calculation efforts.

A further benefit is obtained by:
generating some or all of the samples at non-equidistant sampling times tₙ and
successively approximating the respective time difference tₙ−tₙ₋₁ of two consecutive samples xₙ₋₁ and xₙ, wherein for a potential maximum time difference max {tₙ−tₙ₋₁}=Δ\hat{t} for all the respective order index n>1 and a time difference resolution of M bits, a minimum time step becomes

$$\frac{Δ \hat{t}}{{2}^{M}}$$

and for given time difference tₙ−tₙ₋₁<Δ\hat{t}, a combination of predefined time steps is obtained in that the time difference between the current and the previous sample Δtₙ=tₙ−tₙ₋₁ is quantised with M bits, wherein m=1 represents the most significant bit and m=M the least significant bit and
the approximations starts with a time difference of Δτ₁=Δtₙ.
the quantisation level is defined by

$${T}_{m} = \frac{Δ \hat{t}}{{2}^{m}}$$

and for m=1, it becomes

$${T}_{1} = \frac{Δ \hat{t}}{2}$$

and
the m-th bit follows from

$${w}_{m} = ⌊ \frac{Δ {τ}_{m}}{{T}_{m}} ⌋$$

with

$$Δ {τ}_{m} = Δ {τ}_{m - 1} - {w}_{m - 1} {T}_{m - 1} for m > 1$$

$$Δ {τ}_{m} = Δ {t}_{n} for m = 1$$

the quantised time difference. └⋅┘ denotes the floor operator and for m=1,

$${w}_{1} = ⌊ \frac{Δ {t}_{n}}{{T}_{1}} ⌋ .$$

with all bits computed, the binary word is represented by vector

$$\vec{w} = {( \begin{matrix}{w}_{1} & {w}_{2} & ⋯ & {w}_{M}\end{matrix} )}^{T}$$

with wₘ∈{0,1} for m=1, . . . , M.
and for a set of possible step widths following from Tm

$$\{ {\hat{t}}_{1} , … , {\hat{t}}_{M} \} = \{ {T}_{1} , {T}_{2} , … , {T}_{M} \}$$

the quantised time difference is calculated as

$$Δ τ = ( \begin{matrix}{T}_{1} & {T}_{2} & ⋯ & {T}_{M}\end{matrix} ) \vec{w} = {\sum }_{m = 1}^{M} {w}_{m} {T}_{m} ,$$

which is mapped to the sub-set of predefined DFT vectors needed to obtain the DFT vector \vec{d}⁽ⁿ⁾ for the current time instant tₙ:

$${\vec{d}}^{( n )} = {\prod }_{{w}_{m}} diag \{ {w}_{m} {d}^{\hat{\to }} ( m ) \} {\vec{d}}^{( n - 1 )} for {w}_{m} = 1 and m = 1 , … , M ,$$

wherein only those predefined vectors \vec{\hat{d}}^{(m)} are selected for which wₘ=1.

This implementation provides the benefit that for non-equidistant sampling efficient pre-calculated phasor value may be prepared with fine time granulation. The potential maximum time difference max {tₙ−tₙ₋₁}=Δ\hat{t} is a value that may be set by the skilled person based on the hardware layout of the specific sensor device. I.e. the value may be set such that any time difference value that may be expected in nominal or normal (non-erroneous) operation is considered.

A further benefit is obtained by providing the DFT as an IIR filter-bank implementation of the sample-wise DFT. This provides the benefit that hardware-based processing logic (hardware-filters, e.g., ASICs-application specific integrated circuits) may be used for implementing the method.

As has been described the introduction, the method is particularly advantageous for processing sensor signals of a radar sensor in a vehicle, as a DFT transform of a radar signal allows for analyzing dynamic properties of an object that reflected the radar signal in the environment of the vehicle. A benefit is therefore obtained by: providing the radar signal by a radar sensor and providing, by the processor circuit, the DFT spectral coefficients to a assistance system that controls driving motions of a vehicle and that detects at least one object in an environment of the vehicle based on the DFT spectral coefficients. The DFT spectral coefficients may be processed by the assistance system using a procedure taken from the prior art such that the relative velocity of the object and/or its distance may be derived or obtained from the coefficients. Considering the distance and/or velocity, the assistance system may plan a driving trajectory for the vehicle such that a collision-free motion of the vehicle with regard to the object results. The assistance system may also control at least one actuator of the vehicle (e.g. brakes and/or steering and/or engine) for moving the vehicle according to the trajectory.

For use cases or use situations which may arise in the method and which are not explicitly described here, it may be provided that, in accordance with the method, an error message and/or a prompt for user feedback is output and/or a default settings and/or a predetermined initial state is set.

A further solution is provided by the disclosure in the form of a processor circuit including computer-readable instructions that when executed by the processor circuit cause the processor circuit to perform a method according to an embodiment of the inventive method. Such a processor circuit may be advantageously embedded in a sensor device, in particular a sensor device for a vehicle. Processor circuit may comprise at least one microprocessor and/or at least one microcontroller and/or at least one FPGA (field programmable gate array) and/or at least one DSP (digital signal processor). In particular, a CPU (Central Processing Unit), a GPU (Graphical Processing Unit) or an NPU (Neural Processing Unit) can be used as the respective microprocessor. Furthermore, the processor device may comprise program code which is arranged to perform an embodiment of the method according to the invention when executed by the processor circuit. The program code may be stored in a data memory of the processor circuit. The processor circuit may be based, for example, on at least one circuit board and/or on at least one SoC (system on chip).

A further solution is provided by the disclosure in the form of a sensor device, in particular radar device, comprising an embodiment of the described processor circuit. Additionally or alternatively, the sensor device may comprise a sensor, in particular a radar sensor, for generating a sample-wise sensor signal and a processor circuit, wherein the sensor device, when in operation, performs an embodiment of the method according to the invention. The sensor device may additionally or alternatively comprise a microphone for generating an audio signal, just to name a further example for making use of the invention.

A further solution is provided by the disclosure in the form of a motor vehicle comprising at least one sensor device according to the invention. A motor vehicle can be, for example, in the form of a road vehicle, i.e. a passenger vehicle or a motor bike or a carrier vehicle. The sensor device can be provided for detecting objects in the environment of the vehicle. Such objects can be other traffic participants and/or traffic infrastructure devices (e.g. traffic signs or guard rails).

The disclosure also includes the combinations of the features of the described embodiments.

### BRIEF DESCRIPTION OF THE DRAWINGS

In the following an exemplary implementation of the invention is described. The figures show:

FIG. 1 a schematic illustration of a signal flow of an embodiment of the inventive streaming discrete fourier transform (DFT);

FIG. 2 a schematic illustration of an implementation as IIR filter;

FIG. 3 a schematic illustration of an implementation as a IIR filter-bank implementation of the sample-wise DFT;

FIG. 4 a schematic illustration of an example data flow for a streaming DFT implementation;

FIG. 5 a schematic illustration of data a flow for a streaming DFT implementation when the DFT vectors are recursively computed;

FIG. 6 a schematic illustration of a memory usage for streaming DFT implementations;

FIG. 7 a schematic illustration of a data flow for a streaming with column-wise DFT implementation;

FIG. 8 a schematic illustration of a data flow for a streaming, column-wise DFT implementation;

FIG. 9 a schematic illustration of an M-bit successive approximation of time difference;

FIG. 10 a schematic illustration of a sequence chart for dynamic computation of DFT coefficients suited for non-equidistant sampling;

FIG. 11 a schematic illustration of a dynamic computation of DFT coefficients suited for non-e-quidistant sampling (split into FIG. 11a, 11b, 11c); and

FIG. 12 a schematic illustration of a motor vehicle according to the invention.

### DETAILED DESCRIPTION

In the embodiment described below, the described components of the embodiment each represent individual features which are to be considered independently of each other and which each develop the disclosure also independently of each other and thereby are also to be regarded as a component of the disclosure in individual manner or in another than the shown combination. Furthermore, the described embodiment can also be supplemented by further features of the disclosure already described.

In the figures elements that provide the same function are marked with identical reference signs.

### 1. General Setup

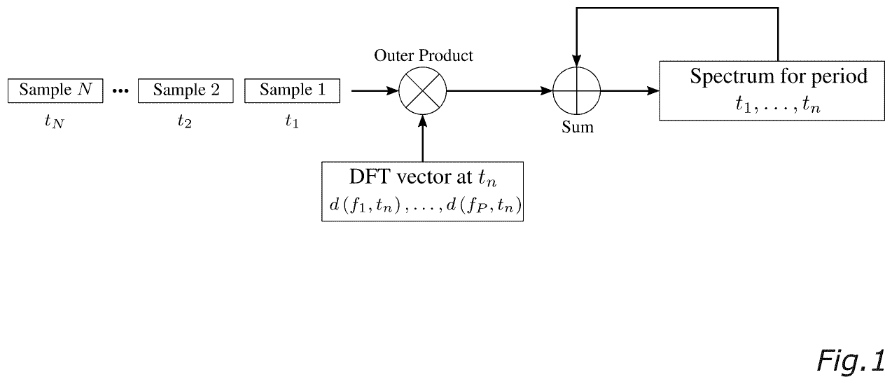

FIG. 1 shows an example implementation as a high-level signal flow of the streaming discrete fourier transform (“DFT”). The stream of time samples comprises Sample 1 to Sample N. The spectral contribution of each time sample is added to the spectrum obtained until current time instant. The illustrated steps can be performed by an processor circuit and implemented by computer-readable instructions and/or by hard-wired processing logic (e.g. as ASIC).

FIG. 1 depicts an abstract signal flow of the streaming DFT. The basic operation is a follows:
A signal sample 1 at time t₁ is fed to an outer-product component. This multiplies the sample 1 with a DFT vector at time t₁. The DFT vector comprises one complex element per frequency, i.e., for P frequencies, the DFT vector is of length P. The output of the outer-product operation is then added to the initial spectrum, which can be a zero vector or any other preloaded vector with one complex element per frequency. It results in a spectrum that represents the time period until t₁.
When a 2nd signal sample 2 at time t₂ arrives, the corresponding DFT vector at time t₂ is multiplied with the signal sample 2 by the outer-product component. The output is then added to the spectrum that has been computed for the period until time t₁ to eventually represent the spectrum for the time period until t₂

This is repeated as long as all time samples 1, 2, . . . , N of consideration are processed to obtain the DFT-transformed signal for the period t₁, t₂, . . . , t_{N}.

### 2. Description: From DFT to Streaming DFT

A signal sampled at time instants t₁, . . . , t_{N} as given by vector

$$\vec{x} = ( \begin{matrix}x ( {t}_{1} ) \\ x ( {t}_{2} ) \\ ⋮ \\ x ( {t}_{N} )\end{matrix} ) = ( \begin{matrix}{x}_{1} \\ {x}_{2} \\ ⋮ \\ {x}_{N}\end{matrix} ) \qquad ( 1 )$$

shall be transformed over the given period via a DFT. With the DFT matrix

$$\tilde{D} = \frac{1}{N} ( \begin{matrix}exp ( - i 2 π {f}_{1} {t}_{1} ) & exp ( - i 2 π {f}_{1} {t}_{2} ) & ⋯ & exp ( - i 2 π {f}_{1} {t}_{N} ) \\ exp ( - i 2 π {f}_{2} {t}_{1} ) & exp ( - i 2 π {f}_{2} {t}_{2} ) & ⋯ & exp ( - i 2 π {f}_{2} {t}_{N} ) \\ ⋮ & ⋮ & ⋱ & ⋮ \\ exp ( - i 2 π {f}_{P} {t}_{1} ) & exp ( - i 2 π {f}_{P} {t}_{2} ) & ⋯ & exp ( - i 2 π {f}_{P} {t}_{N} )\end{matrix} ) \qquad ( 2 )$$

with N the number of time samples, t₁, . . . , t_{N} the sampling time instants, P the number of frequencies and f₁, . . . , fₚ the frequency points, the DFT of \vec{x}(1) follows from

$$\vec{y} = \tilde{D} \vec{x} . \qquad ( 3 )$$

This, however, requires the full vector \vec{x}, i.e., all signal samples have to be stored until the last sample N is available before invoking the DFT computation.

In lieu of capturing firstly all time samples, the contribution of each sample to the DFT spectrum can be computed per each time instant separately—or per subset of all time samples as discussed later. The individual samples Sample 1 to Sample N of a signal sampled in time are consecutively fed to an outer-product component. It consecutively multiplies each sample xₙ=x(tₙ) with the respective DFT vector

$$\begin{matrix}{\vec{d}}^{( n )} = \vec{d} ( {t}_{n} ) \\ = \frac{1}{N} ( \begin{matrix}{d}_{1}^{( n )} \\ {d}_{2}^{( n )} \\ ⋮ \\ {d}_{P}^{( n )}\end{matrix} ) \\ = \frac{1}{N} ( \begin{matrix}d ( {f}_{1} , {t}_{n} ) \\ d ( {f}_{2} , {t}_{n} ) \\ ⋮ \\ d ( {f}_{P} , {t}_{N} )\end{matrix} ) \\ = \frac{1}{N} ( \begin{matrix}exp ( - i 2 π {f}_{1} {t}_{n} ) \\ exp ( - i 2 π {f}_{2} {t}_{n} ) \\ ⋮ \\ exp ( - i 2 π {f}_{P} {t}_{n} )\end{matrix} )\end{matrix} \qquad ( 4 )$$

with n=1, . . . , N. The DFT vector \vec{d}⁽ⁿ⁾ corresponds with the n-th column of the DFT matrix \tilde{D}(2). The output vector

$$Δ {\vec{y}}^{( n )} = {\vec{d}}^{( n )} {x}_{n} \qquad ( 5 )$$

is then added to the spectrum \vec{y}⁽ⁿ⁻¹⁾ that has been obtained for the period t₁ . . . tₙ₋₁. Thus

$${\vec{y}}^{( n )} = Δ {\vec{y}}^{( n )} + {\vec{y}}^{( n - 1 )} = {\vec{d}}^{( n )} {x}_{n} + {\vec{y}}^{( n - 1 )} \qquad ( 6 )$$

yields the spectrum for the period t₁ . . . tₙ with \vec{y}⁽⁰⁾=\vec{0}.

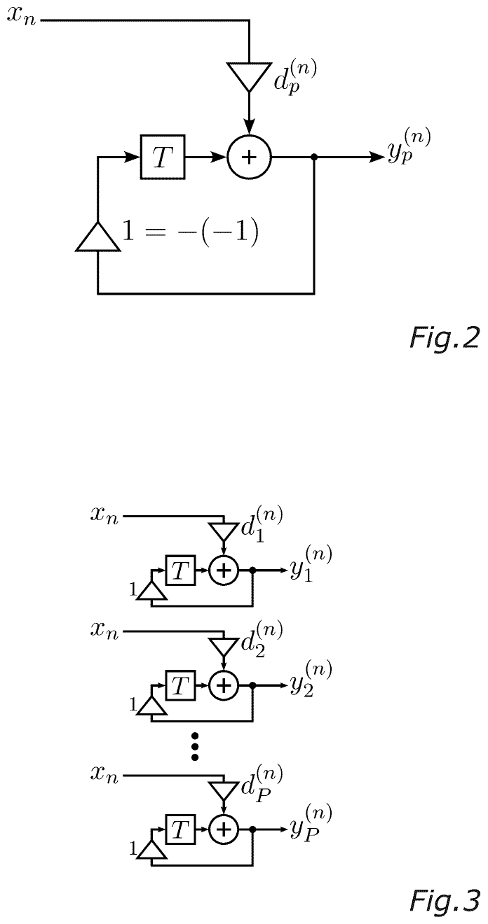

FIG. 2 illustrates an implementation as IIR filter (IRR—infinite impulse response) in transposed direct-form II implementation of the sample-wise DFT for frequency point fₚ using an adaptive feedfoward coefficient

$${d}_{p}^{( n )}$$

in (4).

Equation (6) can be considered a difference equation of an infinite impulse response (IIR) filter bank. Each frequency point fₚ corresponds with an IIR filter that comprises an adaptive filter coefficient in the forward branch. For each element in

$${\vec{y}}^{( n )} = ( \begin{matrix}{y}_{1}^{( n )} \\ {y}_{2}^{( n )} \\ ⋮ \\ {y}_{P}^{( n )}\end{matrix} ) = ( \begin{matrix}y ( {f}_{1} , {t}_{n} ) \\ y ( {f}_{2} , {t}_{n} ) \\ ⋮ \\ y ( {f}_{P} , {t}_{n} )\end{matrix} ) \qquad ( 7 )$$

represents a frequency point of the spectrum, the p-th frequency point is obtained from

$${y}_{p}^{( n )} = {d}_{p}^{( n )} {x}_{n} + {y}_{p}^{( n - 1 )} . \qquad ( 8 )$$

FIG. 2 shows the implementation of difference equation (8) as an IIR filter of feedback order 1. The feedforward coefficients read

$${\vec{b}}_{p , n} = ( {d}_{p}^{( n )} ) , \qquad ( 9 )$$

which reduce to a single adaptive coefficient and the feedback coefficients read

$$\vec{a} = ( \begin{matrix}1 \\ - 1\end{matrix} ) . \qquad ( 10 )$$

FIG. 3 illustrates an implementation as a IIR filter-bank implementation of the sample-wise DFT (6) with one IIR filter element per frequency. Each IIR filter comprises an adaptive feedforward coefficient.

The implementation of the vector difference equation (6) as an adaptive IIR filter bank is depicted in FIG. 3. Each frequency fₚ with p=1, . . . , P is mapped to its respective IIR filter with an adaptive feedforward coefficient

$${d}_{p}^{( n )}$$

(9).

### 3. Algorithmic Implementation

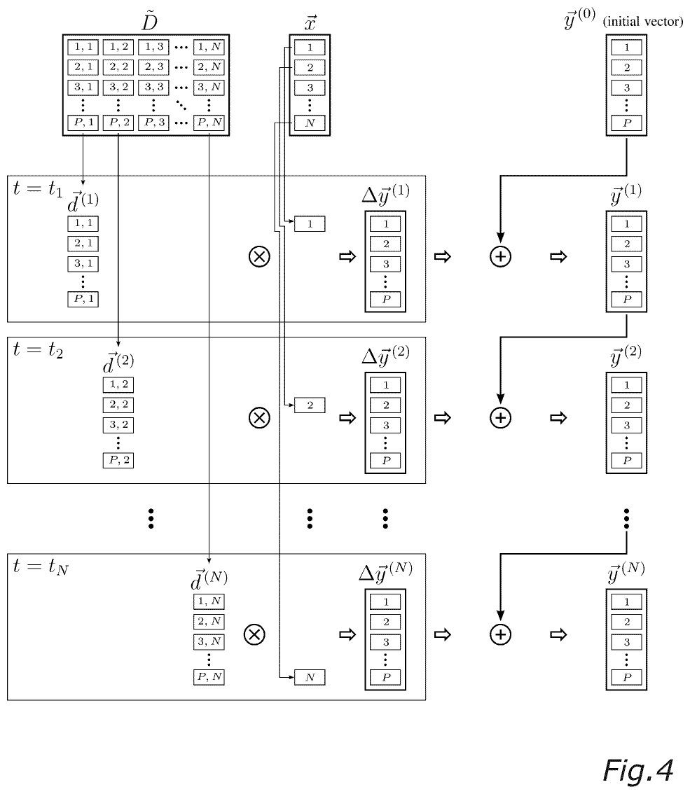

FIG. 4 illustrates an example data flow for a streaming DFT implementation when the DFT matrix as a whole is given. The syntax for the indices is [symbol] for DFT matrix \tilde{D} and DFT vectors \vec{d}⁽ⁿ⁾, [symbol] for \vec{x} and [symbol] for the spectral vectors Δ\vec{y}⁽ⁿ⁾, \vec{y}⁽⁰⁾ and \vec{y}⁽ⁿ⁾ with p=1, . . . , P and n=1, . . . , N.

The data flow of an embodiment of the streaming DFT algorithm is portrayed in FIG. 4. It relies on the following procedure:
t=t₁: Select 1st column of the DFT matrix \vec{d}⁽¹⁾ and multiply it with the 1st signal sample x₁ to obtain the spectral contribution Δ\vec{y}⁽¹⁾.
Add Δ\vec{y}⁽¹⁾ to the initial vector \vec{y}⁽⁰⁾ to obtain the spectrum \vec{y}⁽¹⁾ at frequencies f₁, . . . , fₚ for the 1st time sample.
t=t₂: Select 2nd column of the DFT matrix \vec{d}⁽²⁾ and multiply it with the 2nd signal sample x₂ to obtain the spectral contribution Δ\vec{y}⁽²⁾.
Add Δ\vec{y}⁽²⁾ to the spectrum \vec{y}⁽¹⁾ to obtain the spectrum \vec{y}⁽²⁾ at frequencies f₁, . . . , fₚ for the time period from t₁ to t₂.
. . .
t=tₙ: Select n-th column of the DFT matrix \vec{d}⁽ⁿ⁾ and multiply it with the n-th signal sample xₙ to obtain the spectral contribution Δ\vec{y}⁽ⁿ⁾.
Add Δ\vec{y}⁽ⁿ⁾ to the spectrum \vec{y}⁽ⁿ⁻¹⁾ to obtain the spectrum \vec{y}⁽ⁿ⁾ at frequencies f₁, . . . , fₚ for the time period from t₁ to tₙ.
. . .
t=t_{N}: Select N-th (last) column of the DFT matrix \vec{d}^{(N)} and multiply it with the N-th (last) signal sample x_{N} to obtain the spectral contribution Δ\vec{y}^{(N)}.
Add Δ\vec{y}^{(N)} to the spectrum \vec{y}^{(N-1)} to obtain the spectrum \vec{y}^{(N)} at frequencies f₁, . . . , fₚ for the time period from t₁ to t_{N}.
   \vec{y}^{(N)} can then be used as the DFT of \vec{x}.

The advantage of a step-wise DFT computation lies in the reduced memory consumption needed for the signal samples x₁, . . . , x_{N}. As the spectral contribution of each sample is computed upon its availability, only a single value xₙ needs to be stored. Yet the total memory consumption is still high for storing P×N elements of the DFT matrix.

The memory usage can be further reduced if an equi-distant sampling is given, i.e.,

$${t}_{n} = {t}_{n - 1} + {t}_{0} \qquad ( 11 )$$

with t₀ the sampling period. Then, the DFT vector \vec{d}⁽ⁿ⁾ for a certain time instant tₙ can be obtained from the previous DFT vector \vec{d}⁽ⁿ⁻¹⁾ for the previous time instant tₙ₋₁ by

$${\vec{d}}^{( n )} = diag \{ {\vec{d}}^{( 0 )} \} {\vec{d}}^{( n - 1 )} if n > 1 \qquad ( 12 )$$

with \vec{d}⁽¹⁾ the initial DFT vector and the phasor's vector

$${\vec{d}}^{( 0 )} = ( \begin{matrix}{d}_{1}^{( 0 )} \\ {d}_{2}^{( 0 )} \\ ⋮ \\ {d}_{P}^{( 0 )}\end{matrix} ) = ( \begin{matrix}exp ( - i 2 π {f}_{1} {t}_{0} ) \\ exp ( - i 2 π {f}_{2} {t}_{0} ) \\ ⋮ \\ exp ( - i 2 π {f}_{P} {t}_{0} )\end{matrix} ) . \qquad ( 13 )$$

diag{⋅} denotes the diagonal matrix. \vec{d}⁽ⁿ⁾ (12) basically follows from \vec{d}⁽ⁿ⁻¹⁾ by element-wise multiplication with \vec{d}⁽⁰⁾ or

$${d}_{p}^{( n )} = {d}_{p}^{( n - 1 )} {d}_{p}^{( 0 )} if n > 1. \qquad ( 14 )$$

The initial or 1st DFT vector \vec{d}⁽¹⁾ can be set for an arbitrary time instant t₁.

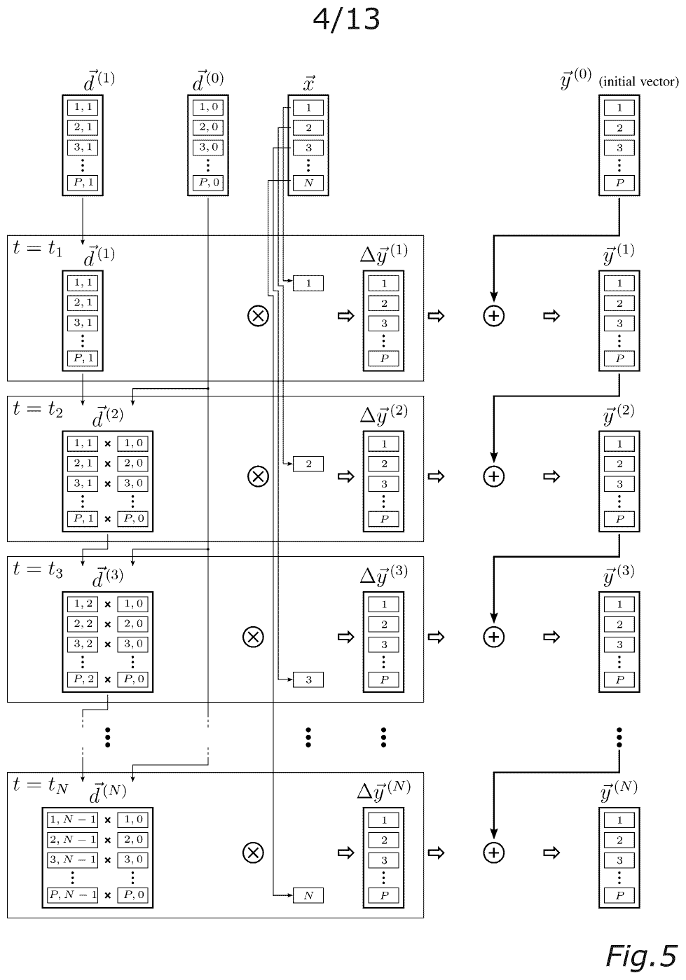

FIG. 5 illustrates an example data flow for a streaming DFT implementation when the DFT vectors are recursively computed, assuming an equi-distant sampling. As of t=t₂, the respective DFT vector follows from the element-wise multiplication of the previous vector and the phasor's vector \vec{d}⁽⁰⁾. The syntax for the indices is [symbol] for DFT vectors \vec{d}⁽ⁿ⁾, [symbol] for \vec{x} and [symbol] for the spectral vectors Δ\vec{y}⁽ⁿ⁾, \vec{y}⁽⁰⁾ and \vec{y}⁽ⁿ⁾ with p=1, . . . , P and n=1, . . . , N.

FIG. 5 depicts the data flow for a streaming DFT implementation leveraging an equi-distant sampling with period t₀.

The algorithm works as follows:
t=t₁: Select the initial DFT vector \vec{d}⁽¹⁾ for an arbitrary time t₁. For example,

$${t}_{1} = 0 , i . e . , {\vec{d}}^{( 1 )} = \vec{1}$$

$$or$$

$${t}_{1} = {t}_{0} , i . e . , {\vec{d}}^{( 1 )} = {\vec{d}}^{( 0 )} .$$

Multiply \vec{d}⁽¹⁾ with the 1st signal sample x₁ to obtain the spectral contribution Δ\vec{y}⁽¹⁾.
Add Δ\vec{y}⁽¹⁾ to the initial vector \vec{y}⁽⁰⁾ to obtain the spectrum \vec{y}⁽¹⁾ at frequencies f₁, . . . , fₚ for the 1st time sample.
t=t₂=t₁+t₀: Compute 2nd DFT vector \vec{d}⁽²⁾ by element-wise multiplication of \vec{d}⁽¹⁾ and \vec{d}⁽⁰⁾ (13).
Multiply \vec{d}⁽²⁾ with the 2nd signal sample x₂ to obtain the spectral contribution Δ\vec{y}⁽²⁾.
Add Δ\vec{y}⁽²⁾ to the spectrum \vec{y}⁽¹⁾ to obtain the spectrum \vec{y}⁽²⁾ at frequencies f₁, . . . , fₚ for the time period from t₁ to t₁+t₀.
. . .
t=tₙ=t₁+(n−1)t₀: Compute n-th DFT vector \vec{d}⁽ⁿ⁾ by element-wise multiplication of \vec{d}⁽ⁿ⁻¹⁾ and \vec{d}⁽⁰⁾ (13).
Multiply \vec{d}⁽ⁿ⁾ with the n-th signal sample xₙ to obtain the spectral contribution Δ\vec{y}⁽ⁿ⁾.
Add Δ\vec{y}⁽ⁿ⁾ to the spectrum \vec{y}⁽ⁿ⁻¹⁾ to obtain the spectrum \vec{y}⁽ⁿ⁾ at frequencies f₁, . . . , fₚ for the time period from t₁ to t₁+ (n−1)t₀.
. . .
t=t_{N}=t₁+ (N−1)t₀: Compute N-th DFT vector \vec{d}^{(N)} by element-wise multiplication of \vec{d}^{(N-1)} and \vec{d}⁽⁰⁾ (13).
Multiply \vec{d}^{(N)} with the N-th (last) signal sample x_{N} to obtain the spectral contribution Δ\vec{y}^{(N)}.
Add Δ\vec{y}^{(N)} to the spectrum \vec{y}^{(N-1)} to obtain the spectrum \vec{y}^{(N)} at frequencies f₁, . . . , fₚ for the time period from t₁ to t₁+ (N−1)t₀.
   \vec{y}^{(N)} can then be used as the DFT of \vec{x}.

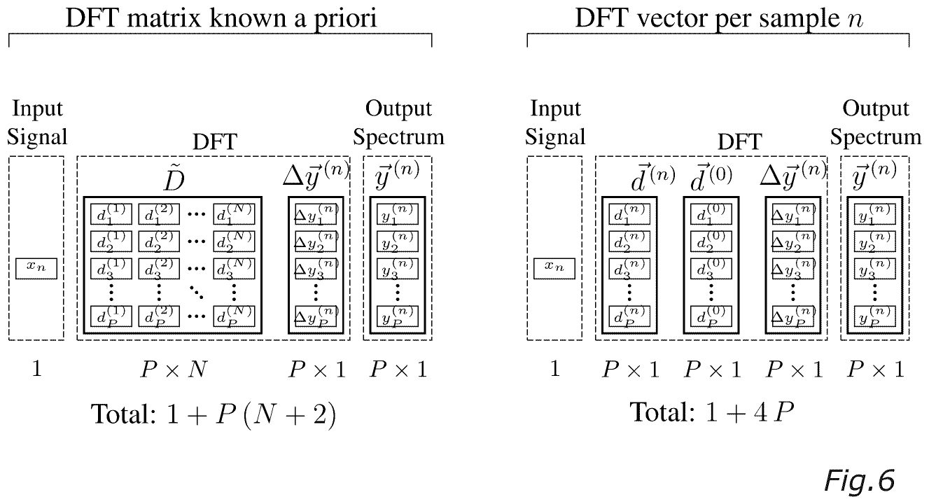

FIG. 6 illustrates a memory usage for streaming DFT implementations: a-priori known DFT matrix (FIG. 4) (left-hand side) and DFT vector computed per n-th time instant (FIG. 5) (right-hand side). The size is given in slices of a certain data type.

FIG. 6 compares the memory usage of the implementation with a-priori known DFT coefficients as depicted in FIG. 4 and the implementation with the DFT vectors computed per n-th time instant as depicted in FIG. 5. For practically meaningful number of time samples N>2, the latter needs less memory. In both cases it is presumed that the delta vector Δ\vec{y} and the output vector \vec{y} are overwritten for each new x₁ when updated. The DFT vector \vec{d}⁽ⁿ⁾ on the right-hand side of FIG. 6 is presumed to overwrite the previous vector \vec{d}⁽ⁿ⁻¹⁾ when multiplied by \vec{d}⁽⁰⁾. The memory usage shown in FIG. 6 is given in slices of a certain data type. Data can be floating or fixed point and of any numeric type such as float or signed integer. The type can represent complex-valued or real-valued data.

### 4. Application to Sequences of Channel Impulse Responses

Let the input signal be a matrix

$$\tilde{x} = ( \begin{matrix}x ( {t}_{1} , {τ}_{1} ) & x ( {t}_{1} , {τ}_{2} ) & ⋯ & x ( {t}_{1} , {τ}_{C} ) \\ x ( {t}_{2} , {τ}_{1} ) & x ( {t}_{2} , {τ}_{2} ) & ⋯ & x ( {t}_{2} , {τ}_{C} ) \\ x ( {t}_{3} , {τ}_{1} ) & x ( {t}_{3} , {τ}_{2} ) & ⋯ & x ( {t}_{3} , {τ}_{C} ) \\ ⋮ & ⋮ & ⋱ & ⋮ \\ x ( {t}_{N} , {τ}_{1} ) & x ( {t}_{N} , {τ}_{2} ) & ⋯ & x ( {t}_{N} , {τ}_{C} )\end{matrix} ) = ( \begin{matrix}{x}_{1 , 1} & {x}_{1 , 2} & ⋯ & {x}_{1 , C} \\ {x}_{2 , 1} & {x}_{2 , 2} & ⋯ & {x}_{2 , C} \\ {x}_{3 , 1} & {x}_{3 , 2} & ⋯ & {x}_{3 , C} \\ ⋮ & ⋮ & ⋱ & ⋮ \\ {x}_{N , 1} & {x}_{N , 2} & ⋯ & {x}_{N , C}\end{matrix} ) \qquad ( 15 )$$

with channel index c=1, . . . , C. In the following, without lack of generality, \tilde{x} is considered a matrix of sampled channel impulse responses. τ_{c} hence is the delay of the c-th path in a multipath environment. Each row of \tilde{x}

$${\vec{x}}_{n}^{T} = ( \begin{matrix}{x}_{n , 1} & {x}_{n , 2} & ⋯ & {x}_{n , C}\end{matrix} ) \qquad ( 16 )$$

represents the channel impulse response at time instant tₙ.

The spectrum of \tilde{x} along the time dimension t follows from

$$\tilde{y} = \tilde{D} \tilde{x} , \qquad ( 17 )$$

which is the equivalent to (3) in matrix notation with D given by (2). The sample-wise DFT per time instant tₙ can therefore computed by means of \vec{d}⁽ⁿ⁾ (4) and the matrix' equivalent to (5) and (6):

$$Δ {\tilde{y}}^{( n )} = {\vec{d}}^{( n )} {\vec{x}}_{n}^{T} \qquad ( 18 )$$

$$and$$

$${\tilde{y}}^{( n )} = Δ {\tilde{y}}^{( n )} + {\tilde{y}}^{( n - 1 )} = {\vec{d}}^{( n )} {\vec{x}}_{n}^{T} + {\tilde{y}}^{( n - 1 )} . \qquad ( 19 )$$

For an equidistant sampling with period t₀ along t, \vec{d}⁽ⁿ⁾ in (19) is obtained from (12) and (13).

\tilde{y}⁽ⁿ⁾ (19) represents the spectrum of \tilde{x} for the period t₁, . . . , t_{N} with \tilde{y}⁽⁰⁾=\tilde{0} for all path delays τ₁, . . . , τ_{c}. As \tilde{x} is considered a matrix of channel impulse responses, \tilde{y} becomes the path-delay Doppler spectrum, which is also known as scattering function or range-Doppler map. Nevertheless, the sample-wise DFT can be applied to any other signal matrix.

### 5. Algorithmic Implementation: Matrix

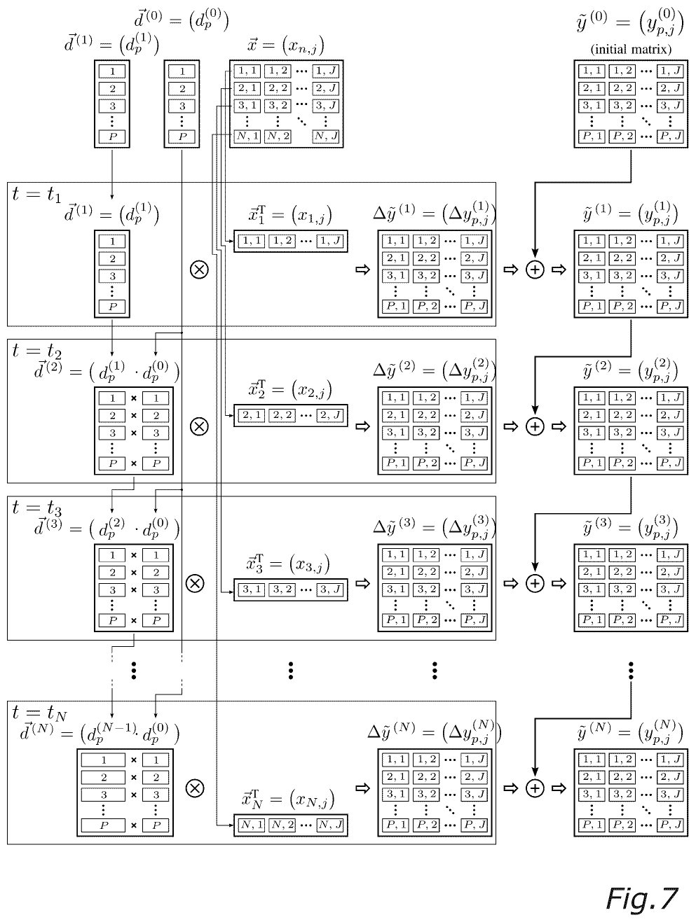

FIG. 7 illustrates an example data flow for a streaming, column-wise DFT implementation applied to a signal matrix \tilde{x} when the DFT vectors are recursively computed, assuming an equi-distant sampling. As of t=t₂, the respective DFT vector follows from the element-wise multiplication of the previous vector and the phasor's vector \vec{d}⁽⁰⁾. The syntax for the indices is [symbol] for DFT vectors \vec{d}⁽⁰⁾ and \vec{d}⁽ⁿ⁾, [symbol] for \tilde{x} and

$${\vec{x}}_{n}^{T}$$

and [symbol] for the spectral matrices Δ\tilde{y}⁽ⁿ⁾ and \tilde{y}⁽ⁿ⁾ with p=1, . . . , P, n=1, . . . , N and j=1, . . . , J.

The data flow of an embodiment of the streaming DFT algorithm applied to a signal matrix is portrayed in FIG. 7. It relies on the following procedure:
t=t₁: Select the initial DFT vector \vec{d}⁽¹⁾ for an arbitrary time t₁. For example,

$${t}_{1} = 0 , i . e . , {\vec{d}}^{( 1 )} = \vec{1}$$

$$or$$

$${t}_{1} = {t}_{0} , i . e . , {\vec{d}}^{( 1 )} = {\vec{d}}^{( 0 )} .$$

Multiply \vec{d}⁽¹⁾ with the 1st row

$${\vec{x}}_{1}^{T}$$

of signal matrix \tilde{x} to obtain the spectral contribution Δ\tilde{y}⁽¹⁾.
Add Δ\tilde{y}⁽¹⁾ to the initial matrix \tilde{y}⁽⁰⁾ to obtain the spectrum \tilde{y}⁽¹⁾ at frequencies f₁, . . . , fₚ for the 1st time sample.
t=t₂=t₁+t₀: Compute 2nd DFT vector \vec{d}⁽²⁾ by element-wise multiplication of \vec{d}⁽¹⁾ and \vec{d}⁽⁰⁾ (13).
Multiply \vec{d}⁽²⁾ with the 2nd row

$${\vec{x}}_{2}^{T}$$

of signal matrix \tilde{x} to obtain the spectral contribution Δ\tilde{y}⁽²⁾.
Add Δ\tilde{y}⁽²⁾ to the spectrum \tilde{y}⁽¹⁾ to obtain the spectrum \tilde{y}⁽²⁾ at frequencies f₁, . . . , fₚ for the time period from t₁ to t₁+t₀.
. . .
t=tₙ=t₁+(n−1)t₀: Compute n-th DFT vector \vec{d}⁽ⁿ⁾ by element-wise multiplication of \vec{d}⁽ⁿ⁻¹⁾ and \vec{d}⁽⁰⁾ (13).
Multiply \vec{d}⁽ⁿ⁾ with the nth row

$${\vec{x}}_{n}^{T}$$

of signal matrix \tilde{x} to obtain the spectral contribution Δ\tilde{y}⁽ⁿ⁾.
Add Δ\tilde{y}⁽ⁿ⁾ to the spectrum \tilde{y}⁽ⁿ⁻¹⁾ to obtain the spectrum \tilde{y}⁽ⁿ⁾ at frequencies f₁, . . . , fₚ for the time period from t₁ to t₁+(n−1)t₀.
. . .
t=t_{N}=t₁+(N−1)t₀: Compute N-th DFT vector \vec{d}^{(N)} by element-wise multiplication of \vec{d}^{(N-1)} and \vec{d}⁽⁰⁾ (13).
Multiply \vec{d}^{(N)} with the N-th (last) row.

$${\vec{x}}_{N}^{T}$$

of signal matrix \tilde{x} to obtain the spectral contribution Δ\tilde{y}^{(N)}.
Add Δ\tilde{y}^{(N)} to the spectrum \tilde{y}^{(N-1)} to obtain the spectrum \tilde{y}^{(N)} at frequencies f₁, . . . , fₚ for the time period from t₁ to t₁+(N−1)t₀.
   \tilde{y}^{(N)} can then be used as the column-wise DFT of \tilde{x}.

### 6. Consideration of Multiple Samples in Time

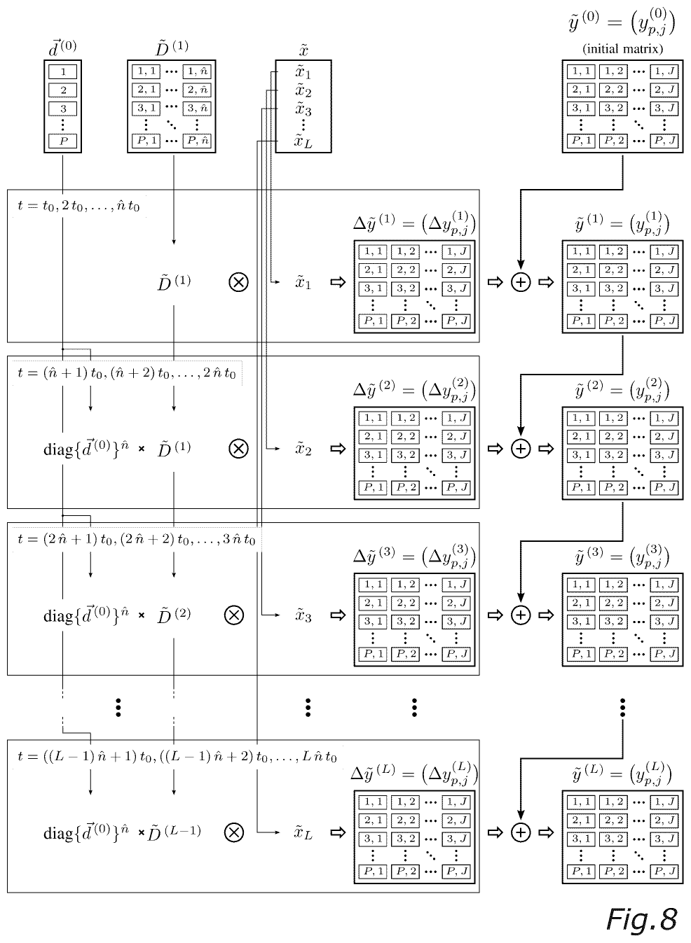

FIG. 8 illustrates a data flow for a streaming, column-wise DFT implementation applied to the signal \tilde{x} when multiple samples (rows) are selected and the DFT matrix per time interval is recursively computed, assuming an equi-distant sampling. The syntax for the indices is [symbol] for DFT phasor \vec{d}⁽⁰⁾, [symbol] for initial DFT matrix \tilde{D}⁽¹⁾ and [symbol] for the spectral matrices Δ\vec{y}⁽ⁿ⁾ and \tilde{y}⁽ⁿ⁾ with p=1, . . . , P, n=1, . . . , \hat{n} and j=1, . . . , J.

A generalisation of the streaming DFT as discussed in Sec. 2, 3 and 4 can be done for a time period of more than one sample. That is, not of single but multiple rows of \tilde{x}(15) are selected to compute their contribution to the spectrum \tilde{y}(17).

Let \hat{n} be the window size, i.e., the number of consecutive samples. Then the input signal matrix (15) can written as

$$\tilde{x} = ( \begin{matrix}{x}_{1 , 1} & {x}_{1 , 2} & ⋯ & {x}_{1 , J} \\ {x}_{2 , 1} & {x}_{2 , 2} & ⋯ & {x}_{2 , J} \\ ⋮ & ⋮ & ⋱ & ⋮ \\ {x}_{\hat{n} , 1} & {x}_{\hat{n} , 2} & ⋯ & {x}_{\hat{n} , J} \\ {x}_{\hat{n} + 1 , 1} & {x}_{\hat{n} + 1 , 2} & ⋯ & {x}_{\hat{n} + 1 , J} \\ {x}_{\hat{n} + 2 , 1} & {x}_{\hat{n} + 2 , 2} & ⋯ & {x}_{\hat{n} + 2 , J} \\ ⋮ & ⋮ & ⋱ & ⋮ \\ {x}_{2 \hat{n} , 1} & {x}_{2 \hat{n} , 2} & ⋯ & {x}_{2 \hat{n} , J} \\ ⋮ & ⋮ & & ⋮ \\ {x}_{( L - 1 ) \hat{n} + 1 , 1} & {x}_{( L - 1 ) \hat{n} + 1 , 2} & ⋯ & {x}_{( L - 1 ) \hat{n} + 1 , J} \\ {x}_{( L - 1 ) \hat{n} + 2 , 1} & {x}_{( L - 1 ) \hat{n} + 2 , 2} & ⋯ & {x}_{( L - 1 ) \hat{n} + 2 , J} \\ ⋮ & ⋮ & ⋱ & ⋮ \\ {x}_{L \hat{n} , 1} & {x}_{L \hat{n} , 2} & ⋯ & {x}_{L \hat{n} , J}\end{matrix} ) \qquad ( 20 )$$

$$or$$

$$\tilde{x} = ( \begin{matrix}{\tilde{x}}_{1} \\ {\tilde{x}}_{2} \\ ⋮ \\ {\tilde{x}}_{L}\end{matrix} ) \qquad ( 21 )$$

with

$${\tilde{x}}_{l} = ( \begin{matrix}{x}_{( l - 1 ) \hat{n} + 1 , 1} & {x}_{( l - 1 ) \hat{n} + 1 , 2} & ⋯ & {x}_{\hat{n} + 1 , J} \\ {x}_{( l - 1 ) \hat{n} + 2 , 1} & {x}_{( l - 1 ) \hat{n} + 2 , 2} & ⋯ & {x}_{( l - 1 ) \hat{n} + 2 , J} \\ ⋮ & ⋮ & ⋱ & ⋮ \\ {x}_{l \hat{n} , 1} & {x}_{l \hat{n} , 2} & ⋯ & {x}_{l \hat{n} , J}\end{matrix} ) , \qquad ( 22 )$$

$$l = 1 , … , L and$$

$$L = ⌊ \frac{N}{\hat{n}} ⌋ . \qquad ( 23 )$$

N is assumed to be an integral multiple of \hat{n}.

The contribution of each \tilde{x}ₗ to the spectrum is obtained by

$$Δ {\tilde{y}}^{( l )} = {\tilde{D}}^{( l )} {\tilde{x}}_{l} . \qquad ( 24 )$$

Assuming an equidistant sampling with period t₀, the DFT matrices \tilde{D}^{(l)} can be computed from an initial matrix

$${\tilde{D}}^{( l )} = \frac{1}{N} ( \begin{matrix}exp ( - i 2 π {f}_{1} {t}_{0} ) & exp ( - i 2 π {f}_{1} 2 {t}_{0} ) & ⋯ & exp ( - i 2 π {f}_{1} \hat{n} {t}_{0} ) \\ exp ( - i 2 π {f}_{2} {t}_{0} ) & exp ( - i 2 π {f}_{2} 2 {t}_{0} ) & ⋯ & exp ( - i 2 π {f}_{2} \hat{n} {t}_{0} ) \\ ⋮ & ⋮ & ⋱ & ⋮ \\ exp ( - i 2 π {f}_{P} {t}_{0} ) & exp ( - i 2 π {f}_{P} 2 {t}_{0} ) & ⋯ & exp ( - i 2 π {f}_{P} \hat{n} {t}_{0} )\end{matrix} ) \qquad ( 25 )$$

and the phasor's vector \vec{d}⁽⁰⁾ (13). With (25) and (13), the l-th DFT matrix reads

$${\tilde{D}}^{( l )} = diag {\{ {\vec{d}}^{( 0 )} \}}^{( l - 1 ) \hat{n}} {\tilde{D}}^{( 1 )} \qquad ( 26 )$$

or in recursive form

$${\tilde{D}}^{( l )} = diag {\{ {\vec{d}}^{( 0 )} \}}^{\hat{n}} {\tilde{D}}^{( l - 1 )} for l > 1. \qquad ( 27 )$$

The spectrum at l-th time window therefore becomes with (22)

$${\tilde{y}}^{( l )} = Δ {\tilde{y}}^{( l )} + {\tilde{y}}^{( l - 1 )} = diag {\{ {\vec{d}}^{( 0 )} \}}^{( l - 1 ) \hat{n}} {\tilde{D}}^{( 1 )} {\tilde{x}}_{l} + {\tilde{y}}^{( l - 1 )} for l > 1 ( 28 ) \qquad ( 28 )$$

$$or$$

$${\tilde{y}}^{( l )} = diag {\{ {\vec{d}}^{( 0 )} \}}^{\hat{n}} {\tilde{D}}^{( l - 1 )} {\tilde{x}}_{l} + {\tilde{y}}^{( l - 1 )} for l > 1 \qquad ( 29 )$$

with \tilde{y}⁽¹⁾=\tilde{D}⁽¹⁾ \tilde{x}₁.

FIG. 8 portrays an implementation of the streaming DFT over multiple samples in time. It works as follows:
t=t₀, 2t₀, . . . , \hat{n} t₀: Select the initial DFT matrix \tilde{D}⁽¹⁾. Multiply \tilde{D}⁽¹⁾ with the 1st sub-matrix \tilde{x}₁ of signal matrix \tilde{x} to obtain the spectral contribution Δ\tilde{y}⁽¹⁾. Add Δ\tilde{y}⁽¹⁾ to the initial matrix \tilde{y}⁽⁰⁾ to obtain the spectrum \tilde{y}⁽¹⁾ at frequencies f₁, . . . , fₚ for the 1st \hat{n} samples.
t=(\hat{n}+1)t₀, (\hat{n}+2)t₀, . . . , 2\hat{n} t₀: Compute 2nd DFT matrix \tilde{D}⁽²⁾ by multiplication of diag{\vec{d}⁽⁰⁾}^{\hat{n}} and \tilde{D}⁽¹⁾ from the previous time interval.
Multiply \tilde{D}⁽²⁾ with the 2nd sub-matrix \tilde{x}₂ of signal matrix \tilde{x} to obtain the spectral contribution Δ\tilde{y}⁽²⁾.
Add Δ\tilde{y}⁽²⁾ to the spectrum \tilde{y}⁽¹⁾ to obtain the spectrum \tilde{y}⁽²⁾ at frequencies f₁, . . . , fₚ for the 2nd \hat{n} samples.
. . .
t=((l−1)ñ+1)t₀, ((l−1)ñ+2)t₀, . . . , lñ t₀: Compute l-th DFT matrix \tilde{D}^{(l)} by multiplication of diag{\vec{d}⁽⁰⁾}^{\hat{n}} and \tilde{D}(l−1) from the (l−1)-th time interval.
Multiply \tilde{D}^{(l)} with the l-th sub-matrix \tilde{x}ₗ of signal matrix \tilde{x} to obtain the spectral contribution Δ\tilde{y}^{(l)}.
Add Δ\tilde{y}^{(l)} to the spectrum \tilde{y}^{(l-1)} to obtain the spectrum \tilde{y}^{(l)} at frequencies f₁, . . . , fₚ for the l-th \hat{n} samples.
t=((L−1)\hat{n}+1)t₀, ((L−1)\hat{n}+2)t₀, . . . , L\hat{n} t₀: Compute L-th DFT matrix \tilde{D}^{(L)} by multiplication of diag{\vec{d}⁽⁰⁾} and \tilde{D}^{(L-1)} from the (L−1)-th time interval.
Multiply \tilde{D}^{(L)} with the L-th sub-matrix \tilde{x}_{L} of signal matrix \tilde{x} to obtain the spectral contribution Δ\tilde{y}(L).
Add Δ\tilde{y}^{(L)} to the spectrum \tilde{y}^{(L-1)} to obtain the spectrum \tilde{y}^{(L)} at frequencies f₁, . . . , fₚ for the L-th \hat{n} samples.

\tilde{y}^{(L)} can then be used as the column-wise DFT of \tilde{x}.

### 7. Implementation for Non-Equidistant Sampling

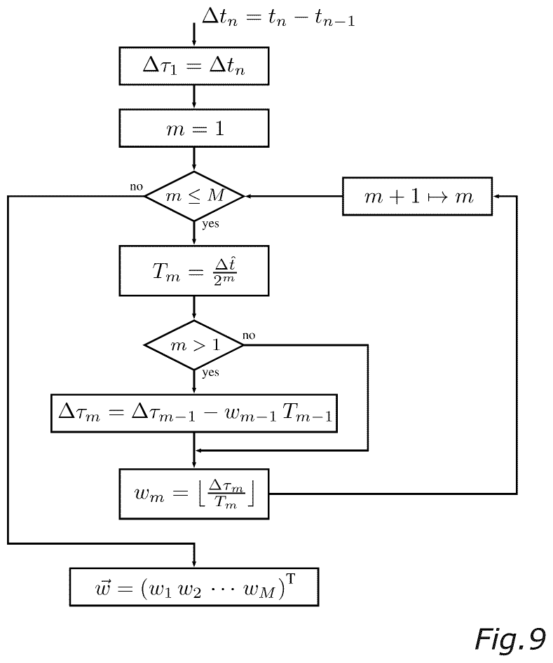

FIG. 9 illustrates an M-bit successive approximation of time difference Δtₙ (40). Based on the output vector \vec{w} (45), the sub-set of predefined DFT vectors (37) is selected and combined to compute the contribution of the sample at time instant tₙ to the DFT.
The DFT matrix as defined by \tilde{D}(2) does not imply an equidistant sampling, i.e., in general

$${t}_{n} - {t}_{n - 1} \neq const for n = 1 , … , N . \qquad ( 30 )$$

For a given period t₁ to t_{N} the full DFT matrix has to be stored in memory.

Alternatively, the DFT vector \vec{d}⁽ⁿ⁾ (4) can be computed based on its predecessor \vec{d}⁽ⁿ⁻¹⁾ as pointed out for the equidistant case in Sec. 3. This can basically be done in two ways:
A minimum step width \hat{t}₀ is set and \vec{d}⁽ⁿ⁾ is obtained from

$${\vec{d}}^{( n )} = diag {\{ {\vec{d}}^{( 0 )} \}}^{μ} {\vec{d}}^{( n - 1 )} for n > 1 \qquad ( 31 )$$

with

$${{d}^{( 0 )}}^{\hat{\to }} = ( \begin{matrix}exp ( - i 2 π {f}_{1} {\hat{t}}_{0} ) \\ exp ( - i 2 π {f}_{2} {\hat{t}}_{0} ) \\ ⋮ \\ exp ( - i 2 π {f}_{P} {\hat{t}}_{0} )\end{matrix} ) \qquad ( 32 )$$

$$and$$

$$μ = [ \frac{{t}_{n} - {t}_{n - 1}}{{\hat{t}}_{0}} ] \qquad ( 33 )$$

the integer multiple of the time difference tₙ−tₙ₋₁ over the step width \hat{t}₀; [⋅] denotes the rounding operator. As a consequence of rounding, the time step μ \hat{t}₀, can differ from the actual time difference tₙ−tₙ₋₁, leading to computation errors in the DFT. \hat{t}₀, is therefore assumed to be a little fractional of the minimum time difference expected, for example,

$${\hat{t}}_{0} << min \{ {t}_{n} - {t}_{n - 1} \} ∀ n > 1. \qquad ( 34 )$$

Whilst in this case \vec{\hat{d}}⁽⁰⁾ (32) is the only DFT vector to be permanently stored in memory, the computation effort can become high for large μ.
For reduced computation effort, a set of possible step width

$$\{ {\hat{t}}_{1} , … , {\hat{t}}_{M} \} \qquad ( 35 )$$

can be put. Then

$${\vec{d}}^{( n )} = diag \{ {{d}^{( m )}}^{\hat{\to }} \} {\vec{d}}^{( n - 1 )} for n > 1 and m = 1 , … , M \qquad ( 36 )$$

with

$${{d}^{( m )}}^{\hat{\to }} = ( \begin{matrix}exp ( - i 2 π {f}_{1} {\hat{t}}_{m} ) \\ exp ( - i 2 π {f}_{2} {\hat{t}}_{m} ) \\ ⋮ \\ exp ( - i 2 π {f}_{P} {\hat{t}}_{m} )\end{matrix} ) \qquad ( 37 )$$

$$m = argmin \vert \{ {t}_{n} - {t}_{n - 1} - {\hat{t}}_{m} \} \vert . \qquad ( 38 )$$

Descriptively speaking, it is taken that time step \hat{t}ₘ that is closest to the time difference tₙ−tₙ₋₁ of two consecutive samples.

Compared to the former cases, M DFT vectors need to be permanently stored in memory in favour of reduced computation effort.

Also combinations of both abovementioned approaches can be applied.

A certain implementation is based on a successive approximation to the time difference tₙ−tₙ₋₁ of two consecutive samples. Suppose a maximum time difference

$$max \{ {t}_{n} - {t}_{n - 1} \} = Δ \hat{t} ∀ n \qquad ( 39 )$$

and a time difference resolution of M bits, i.e., the minimum time step becomes

$$\frac{Δ \hat{t}}{{2}^{M}} .$$

For a certain time difference tₙ-tₙ₋₁<Δ\hat{t}, a combination of predefined time steps can be obtained. FIG. 9 shows the implementation:
The time difference between the current and the previous sample is denoted as

$$Δ {t}_{n} = {t}_{n} - {t}_{n - 1} . \qquad ( 40 )$$

Δtₙ is to be quantised with M bits. m=1 represents the most significant bit, m=M the least significant bit.
The approximations starts with a time difference of Δτ₁=Δtₙ.
The quantisation level is defined by

$${T}_{m} = \frac{Δ \hat{t}}{{2}^{m}} . \qquad ( 41 )$$

For m=1, it becomes

$${T}_{1} = \frac{Δ \hat{t}}{2} .$$

The m-th bit follows from

$${w}_{m} = ⌊ \frac{Δ {τ}_{m}}{{T}_{m}} ⌋ \qquad ( 42 )$$

with

$$Δ {τ}_{m} = Δ {τ}_{m - 1} - {w}_{m - 1} {T}_{m - 1} for m > 1 \qquad ( 43 )$$

$$Δ {τ}_{m} = Δ {t}_{n} for m = 1 \qquad ( 44 )$$

the quantised time difference. └⋅┘ denotes the floor operator. For m=1,

$${w}_{1} = ⌊ \frac{Δ {t}_{n}}{{T}_{1}} ⌋ .$$

With all bits computed, the binary word is represented by vector

$$\vec{w} = {( \begin{matrix}{w}_{1} & {w}_{2} & ⋯ & {w}_{M}\end{matrix} )}^{T} \qquad ( 45 )$$

with wₘ└{0,1} for m=1, . . . , M.

For a set of possible step widths (35) following from (41)

$$\{ {\hat{t}}_{1} , … , {\hat{t}}_{M} \} = \{ {T}_{1} , {T}_{2} , … , {T}_{M} \} \qquad ( 46 )$$

the quantised time difference follows from

$$Δ τ = ( \begin{matrix}{T}_{1} & {T}_{2} & ⋯ & {T}_{M}\end{matrix} ) \vec{w} = {\sum }_{m = 1}^{M} {w}_{m} {T}_{m} . \qquad ( 47 )$$

This can be mapped to the sub-set of predefined DFT vectors (37) needed to obtain the DFT vector \vec{d}⁽ⁿ⁾ for the current time instant tₙ:

$${\vec{d}}^{( n )} = {\prod }_{{w}_{m}} diag \{ {w}_{m} {{d}^{\hat{\to }}}^{( m )} \} {\vec{d}}^{( n - 1 )} \qquad ( 48 )$$

$$for {w}_{m} = 1 and m = 1 , … , M .$$

That is, only those predefined vectors \vec{\hat{d}}^{(m)} are selected for which wₘ=1.

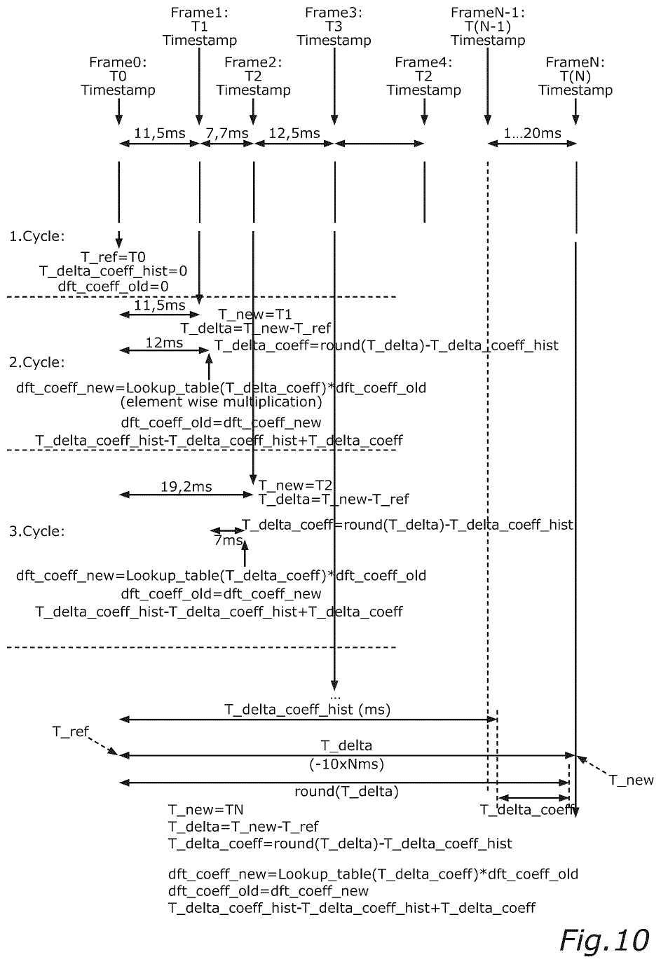

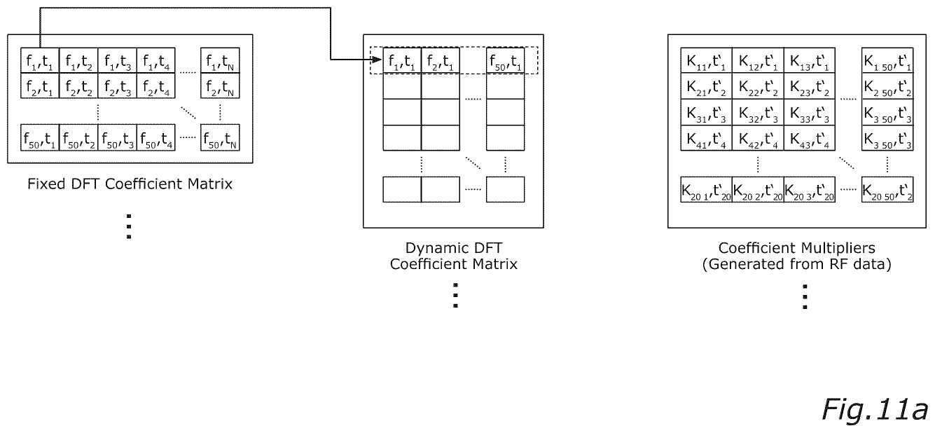

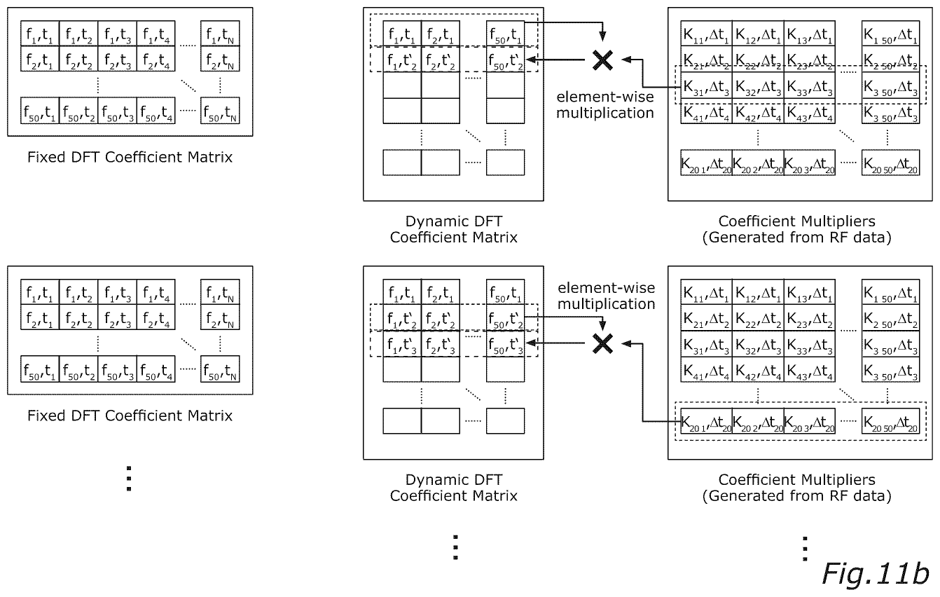

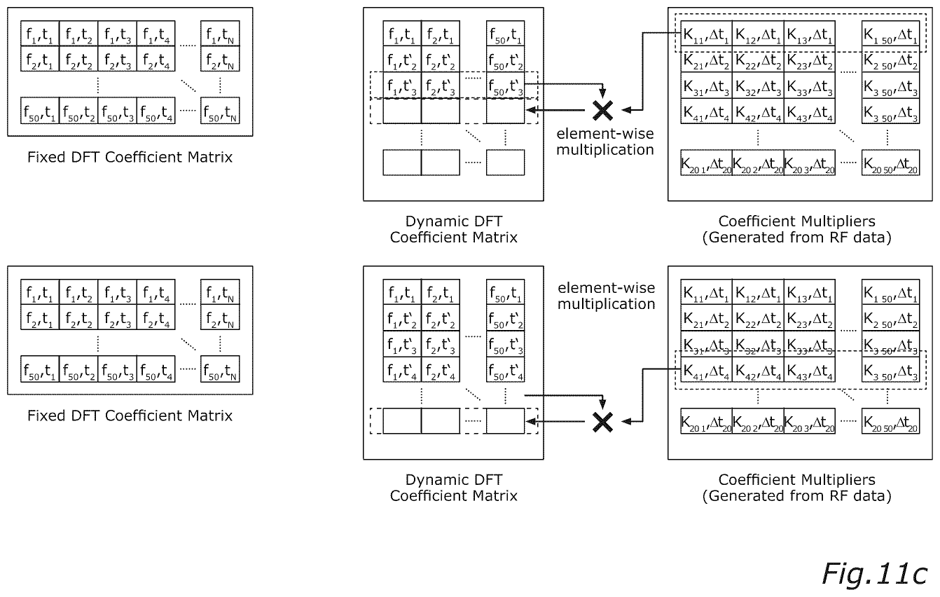

An implementation for dynamically DFT coefficient calculations for non-equidistant sampling is depicted in FIG. 10 and FIG. 11.

FIG. 10 illustrates a sequence chart for dynamic computation of DFT coefficients suited for non-equidistant sampling.

FIG. 11 (split into FIG. 11a, FIG. 11b, FIG. 11c) illustrates a dynamic computation of DFT coefficients suited for non-e-quidistant sampling.

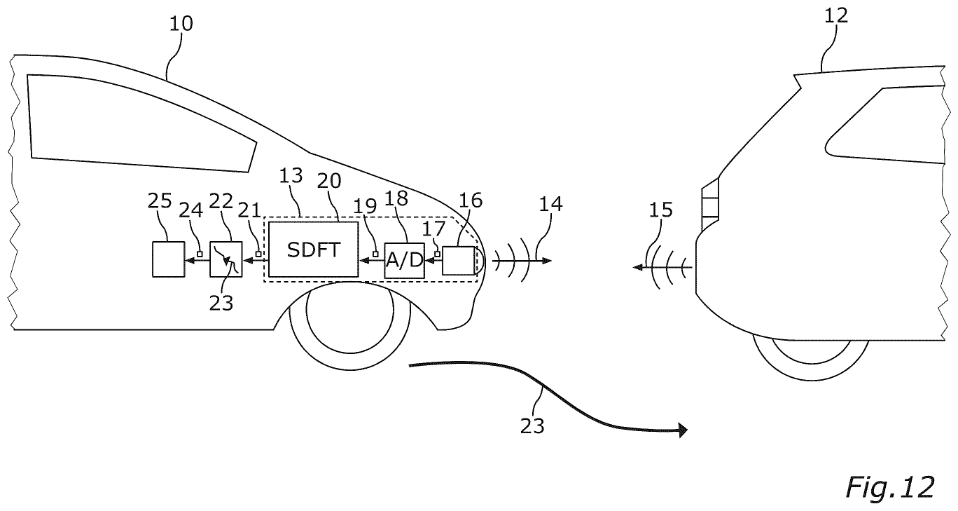

FIG. 12 illustrates motor vehicle 10 that can be, e.g., a passenger vehicle, that is driving on a road. In an environment 11 of the vehicle 10, objects 12, like, e.g. other traffic participant, can be detected by a sensor device 13 of the vehicle 10. The sensor device 13 can be a radar device that can emit radar waves 14 which may be reflected by one or more of the objects 12 and may then return as reflected radar waves 15 to the sensor device 13. A radar sensor 16 may receive the reflected radar waves 15 and may generate a sensor signal 17 from the received radar waves. An analog-to-digital conversion 18 may convert the sensor signal 17 into single samples 19 that one after another may be received by a processor circuit 20. It is also possible to provide a multi-channel version as described above. The generation of the samples 19 from reflected radar waves 15 can be implemented as is known from the prior art.

Whenever the processor circuit 20 receives a new sample 19, a timestamp may be associated with the sample 19 indicating, e.g., the time of reception or generation. The processor circuit 20 can transform the samples 19 into DFT coefficients 21 using one or more of the described procedures thus applying the SDFT.

An assistance system 22, e.g. an autonomous driving function or a driver assistance system, can use the DFT coefficients 21 for detecting the objects 12 and/or for analyzing the relative distance and/or velocity of the objects 12 with regard to the sensor 16. Using the DFT coefficients 21 and by a procedure known from the prior art the assistance system 22 can calculate a driving trajectory 23 for avoiding a collision with the objects 12. For controlling the vehicle 10 such that it follows the trajectory 23, the assistance system 22 can generate control commands 24 that control or influence at least one actuator 25 of the vehicle 10, e.g. a brake and/or a steering and/or an engine.

Overall, the example shows how an implementation of a Streaming Discrete Fourier Transform, SDFT, is provided by the invention.

### REFERENCE SIGNS

10 vehicle
11 environment
12 objects
13 sensor device
14 emitted radar waves
15 received radar waves
16 sensor
17 sensor signal
18 analog-to-digital conversion
19 sample
20 processor circuit
21 DFT coefficients
22 assistance system
23 driving trajectory
24 control commands
25 actuator

1. A method for applying a P-dimensional discrete Fourier transform (“DFT”) to a sequence of N samples of a sensor signal, with P, N>2, comprising:
receiving one of the samples at a time at a processor circuit; and
performing the following in response to receiving a new one of the samples or a group of consecutive new samples, comprising a predefined number J of samples, with 1<J<N
providing, for each new sample xₙ, an order index n indicating which one of the 1 to N samples has been received, wherein n in 1, . . . , N,
proving, for each new sample, a corresponding DFT vector \vec{d}⁽ⁿ⁾, wherein the DFT vector \vec{d}⁽ⁿ⁾ is selected or generated depending on the order index n of the sample, wherein the DFT vector \vec{d}⁽ⁿ⁾ comprises P phasor values that are derived from frequency points fₚ of the P-dimensional DFT by S*exp(−i 2 π fₚ tₙ) with p in 1, . . . , P the index of the phasor value in the DFT vector \vec{d}⁽ⁿ⁾ and S a scaling factor and tₙ the sampling time of the new sample xₙ and i the imaginary unit with i²=−1;
applying the respective new sample xₙ as a multiplication factor to its corresponding DFT vector \vec{d}⁽ⁿ⁾ for generating a respective spectral contribution vector Δ\vec{y}⁽ⁿ⁾=\vec{d}⁽ⁿ⁾ xₙ;
adding the respective spectral contribution vector Δ\vec{y}⁽ⁿ⁾ to an accumulation vector \vec{y}⁽ⁿ⁾=Δ\vec{y}⁽ⁿ⁾+\vec{y}⁽ⁿ⁻¹⁾,
when for all N samples their corresponding resulting contribution vector has been added to the accumulation vector, providing the accumulation vector \vec{y}^{(N)} as DFT spectral coefficients of the N samples.

2. The method according to claim 1, further comprising deleting the respective new sample when the corresponding contribution vector for that sample is calculated and deleting the respective contribution vector after adding it to the accumulation vector, such that at no point in time all N samples xₙ, with n in 1, . . . , N, nor their resulting contribution vector Δ\vec{y}⁽ⁿ⁾ are stored together in the processor circuit.

3. The method according to claim 1, further comprising:
generating at least some or all of the samples at sampling times with constant sampling period t₀, resulting in tₙ=tₙ₋₁+t₀ for n in 2, . . . N and t₁ an initial time value, in particular t₁=0; and
generating the respective DFT vector \vec{d}⁽ⁿ⁾ for the respective sample xₙ of order index n using a P-dimensional base DFT vector \vec{d}⁽⁰⁾ and the DFT vector \vec{d}⁽ⁿ⁻¹⁾ by applying an element-wise multiplication \vec{d}⁽ⁿ⁾=diag{\vec{d}⁽⁰⁾}\vec{d}⁽ⁿ⁻¹⁾, if n>1 and diag{⋅} the diagonal matrix, wherein \vec{d}⁽⁰⁾ comprises phasor elements exp(−i 2 π fₚ t₀) with p in 1, . . . , P.

4. The method according to claim 1, further comprising:
generating at least some or all of the samples at non-equidistant sampling times tₙ;
providing a rasterized time pattern by defining a minimum time step width \hat{t}₀; and
generating the respective DFT vector \vec{d}⁽ⁿ⁾ for the respective sample of order index n using a P-dimensional base DFT vector \vec{\hat{d}}⁽⁰⁾ and the DFT vector \vec{d}⁽ⁿ⁻¹⁾ by applying a element-wise multiplication, wherein \vec{\hat{d}}⁽⁰⁾ comprises phasor elements exp(−i 2 π fₚ \hat{t}₀) with p in 1, . . . , P and a time difference tₙ−tₙ₋₁ of sampling time of the last sample xₙ and the preceding sample xₙ₋₁ is expressed as the integer multiple or the next larger integer multiple or the next smaller integer multiple
$$μ = [ \frac{{t}_{n} - {t}_{n - 1}}{{\hat{t}}_{0}} ]$$
of \hat{t}₀, with [⋅] the rounding operator, such that \vec{d}⁽ⁿ⁾=diag{\vec{\hat{d}}⁽⁰⁾}^{μ} \vec{d}⁽ⁿ⁻¹⁾.

5. The method according to claim 1, further comprising:
generating at least some or all of the samples at non-equidistant sampling times tₙ; and
keeping stored M>1 pre-calculated vectors diag{\vec{\hat{d}}^{(m)}} for different time values {\hat{t}₁, . . . , \hat{t}_{M}} are kept stored in memory as \vec{\hat{d}}^{(m)}, m=1 . . . M, with phasor elements exp(−i 2 π fₚ \hat{t}ₘ), p=1, . . . , P, and for a given sample xₙ at sampling time tₙ the vector for index m=arg min|{tₙ−tₙ₋₁−\hat{t}ₘ}| with the closest time-difference is applied by element-wise multiplication to the preceding DFT vector for providing the DFT vector \vec{d}⁽ⁿ⁾=diag{\vec{\hat{d}}(m)}\vec{d}⁽ⁿ⁻¹⁾ for n>1.

6. The method according to claim 1, further comprising receiving the new sample xₙ from a first channel τ₁ giving a new first-channel sample x(tₙ, τ₁) and receiving together with this new first-channel sample at least one further new sample x(tₙ, τ_{c}) for at least one further channel c, such that overall a respective new sample of C channels are received and transforming the new samples x(tₙ, τ_{c}), c=1, . . . , C, together for each channel, c=1, . . . , C.

7. The method according to claim 1, further comprising:
generating at least some or all of the samples at non-equidistant sampling times tₙ; and
providing for M>1 a set of possible time step widths
$$\{ {\hat{t}}_{1} , … , {\hat{t}}_{M} \}$$
and for sample xₙ it is taken that time step \hat{t}ₘ that is closest to the time difference tₙ−tₙ₋₁ of two consecutive samples
$${\vec{d}}^{( n )} = diag \{ {d}^{\hat{\to }} ( m ) \} {\vec{d}}^{( n - 1 )} for n > 1 and m = 1 , … , M$$
with
$${{d}^{\hat{\to }}}^{( m )} = ( \begin{matrix}exp ( - i 2 π {f}_{1} {\hat{t}}_{m} ) \\ exp ( - i 2 π {f}_{2} {\hat{t}}_{m} \\ ⋮ \\ exp ( - i 2 π {f}_{P} {\hat{t}}_{m} )\end{matrix} ) and$$
$$m = arg min \vert \{ {t}_{n} - {t}_{n - 1} - {\hat{t}}_{m} \} \vert .$$

8. The method according to claim 1, further comprising:
generating at least some or all of the samples at non-equidistant sampling times tₙ; and
successively approximating the respective time difference tₙ−tₙ₋₁ of two consecutive samples xₙ₋₁ and xₙ, wherein for a maximum time difference max {tₙ−tₙ₋₁}=Δ\hat{t} for the respective order index n and a time difference resolution of M bits, a minimum time step becomes
$$\frac{Δ \hat{t}}{{2}^{M}}$$
and for given time difference tₙ−tₙ₋₁≤Δ\hat{t}, a combination of predefined time steps is obtained in that the time difference between the current and the previous sample is Δtₙ=tₙ−tₙ₋₁ and Δtₙ is quantised with M bits, wherein m=1 represents the most significant bit and m=M the least significant bit, wherein
the approximations starts with a time difference of Δτ₁=Δtₙ,
the quantisation level is defined by
$${T}_{m} = \frac{Δ \hat{t}}{{2}^{m}} ,$$
for m=1, it becomes
$${T}_{1} = \frac{Δ \hat{t}}{2} ,$$
and
the m-th bit follows from
$${w}_{m} = ⌊ \frac{Δ {τ}_{m}}{{T}_{m}} ⌋$$
with
$$Δ {τ}_{m} = Δ {τ}_{m - 1} - {w}_{m - 1} {T}_{m - 1} for m > 1$$
$$Δ {τ}_{m} = Δ {t}_{n} for m = 1$$
the quantised time difference. └⋅┘ denotes the floor operator and for m=1,
$${w}_{1} = ⌊ \frac{Δ {t}_{n}}{{T}_{1}} ⌋ .$$
with all bits computed, the binary word is represented by vector
$$\vec{w} = {( \begin{matrix}{w}_{1} & {w}_{2} & ⋯ & {w}_{M}\end{matrix} )}^{T}$$
with wₘ∈{0,1} for m=1, . . . , M
and for a set of possible step widths following from Tₘ
$$\{ {\hat{t}}_{1} , … , {\hat{t}}_{M} \} = \{ {T}_{1} , {T}_{2} , … , {T}_{M} \}$$
the quantised time difference is calculated as
$$Δ τ = ( \begin{matrix}{T}_{1} & {T}_{2} & ⋯ & {T}_{M}\end{matrix} ) \vec{w} = {\sum }_{m = 1}^{M} {w}_{m} {T}_{m} ,$$
which is mapped to the sub-set of predefined DFT vectors (37) needed to obtain the DFT vector \vec{d}⁽ⁿ⁾ for the current time instant tₙ:
$${\vec{d}}^{( n )} = {\prod }_{{w}_{m}} diag \{ {w}_{m} {d}^{\hat{\to }} ( m ) \} {\vec{d}}^{( n - 1 )} for {w}_{m} = 1 and m = 1 , … , M ,$$
wherein only those predefined vectors \vec{\hat{d}}^{(m)} are selected for which wₘ=1.

9. The method according to claim 1, further comprising providing the DFT as a IIR filter-bank implementation of the sample-wise DFT.

10. The method according to claim 1, further comprising:
providing the radar signal by a radar sensor; and
providing, by the processor circuit, the DFT spectral coefficients to a assistance system that controls driving motions of a vehicle and that detects at least one object in an environment of the vehicle based on the DFT spectral coefficients.

11. A processor circuit for applying a P-dimensional discrete Fourier transform (“DFT”) to a sequence of N samples of a sensor signal, with P, N>2, and configured to:
receive one of the samples at a time; and
perform the following in response to receiving a new one of the samples or a group of consecutive new samples, comprising a predefined number J of samples, with 1<J<N
provide, for each new sample xₙ, an order index n indicating which one of the 1 to N samples has been received, wherein n in 1, . . . , N,
prove, for each new sample, a corresponding DFT vector \vec{d}⁽ⁿ⁾, wherein the DFT vector \vec{d}⁽ⁿ⁾ is selected or generated depending on the order index n of the sample, wherein the DFT vector \vec{d}⁽ⁿ⁾ comprises P phasor values that are derived from frequency points fₚ of the P-dimensional DFT by S*exp(−i 2 π fₚ tₙ) with p in 1, . . . , P the index of the phasor value in the DFT vector \vec{d}⁽ⁿ⁾ and S a scaling factor and tₙ the sampling time of the new sample xₙ and i the imaginary unit with i²=−1;
apply the respective new sample xₙ as a multiplication factor to its corresponding DFT vector \vec{d}⁽ⁿ⁾ for generating a respective spectral contribution vector Δ\vec{y}⁽ⁿ⁾=\vec{d}⁽ⁿ⁾xₙ; and
add the respective spectral contribution vector Δ\vec{y}⁽ⁿ⁾ to an accumulation vector \vec{y}⁽ⁿ⁾=Δ\vec{y}⁽ⁿ⁾+\vec{y}⁽ⁿ⁻¹⁾,
when for all N samples their corresponding resulting contribution vector has been added to the accumulation vector, provide the accumulation vector \vec{y}^{(N)} as DFT spectral coefficients of the N samples.

12. A RADAR device, comprising:
a sensor for generating a sensor signal; and
a processor circuit for applying a P-dimensional discrete Fourier transform (“DFT”) to a sequence of N samples of the sensor signal, with P, N>2, and configured to
receive one of the samples at a time, and
perform the following in response to receiving a new one of the samples or a group of consecutive new samples, comprising a predefined number J of samples, with 1<J<N
provide, for each new sample xₙ, an order index n indicating which one of the 1 to N samples has been received, wherein n in 1, . . . , N,
prove, for each new sample, a corresponding DFT vector \vec{d}⁽ⁿ⁾, wherein the DFT vector \vec{d}⁽ⁿ⁾ is selected or generated depending on the order index n of the sample, wherein the DFT vector \vec{d}⁽ⁿ⁾ comprises P phasor values that are derived from frequency points fₚ of the P-dimensional DFT by S*exp(−i 2 π fₚ tₙ) with p in 1, . . . , P the index of the phasor value in the DFT vector \vec{d}⁽ⁿ⁾ and S a scaling factor and tₙ the sampling time of the new sample xₙ and i the imaginary unit with i²=−1;
apply the respective new sample xₙ as a multiplication factor to its corresponding DFT vector \vec{d}⁽ⁿ⁾ for generating a respective spectral contribution vector Δ\vec{y}⁽ⁿ⁾=\vec{d}⁽ⁿ⁾ xₙ; and
add the respective spectral contribution vector Δ\vec{y}⁽ⁿ⁾ to an accumulation vector \vec{y}⁽ⁿ⁾=Δ\vec{y}⁽ⁿ⁾+\vec{y}⁽ⁿ⁻¹⁾,
when for all N samples their corresponding resulting contribution vector has been added to the accumulation vector, provide the accumulation vector \vec{y}^{(N)} as DFT spectral coefficients of the N samples.
